(19) United States
(12) Patent Application Publication
(10) Pub. No.: US 2013/0248833 A1
(43) Pub. Date: Sep. 26, 2013

(54) MODULAR STRATEGY FOR INTRODUCING END-GROUP FUNCTIONALITY INTO CONJUGATED COPOLYMERS

(71) Applicant: THE REGENTS OF THE UNIVERSITY OF CALIFORNIA, Oakland, CA (US)

(72) Inventors: Craig J. Hawker, Santa Barbara, CA (US); Michael L. Chabinyc, Santa Barbara, CA (US); Sung-Yu Ku, Goleta, CA (US); Maxwell J. Robb, Santa Barbara, CA (US)

(73) Assignee: The Regents of the University of California, Oakland, CA (US)

(21) Appl. No.: 13/850,040

(22) Filed: Mar. 25, 2013

Related U.S. Application Data
(60) Provisional application No. 61/615,310, filed on Mar. 25, 2012.

(51) Int. Cl. H01L 51/00

(52) U.S. Cl. CPC H01L 51/0043
USPC 257/40; 525/274; 422/131

(57) ABSTRACT

The invention provides methods for making and using end-functionalized conjugated polymers. Embodiments of the invention comprise performing a coupling polymerization in the presence of AA monomers, BB monomers and an end capping compound that can react with a monomer and which is selected to include a functional group. The functional end groups can, for example, comprise polymers or small molecules selected for their ability to produce conjugated polymers that self-assemble into thermodynamically ordered structures. In certain embodiments of the invention, nano-scale morphology of such conjugated polymer compositions can be driven by the phase separation of two covalently bound polymer blocks. These features make the use of conjugated polymers an appealing strategy for exerting control over active layer morphology in semiconducting polymer materials systems.

### REFERENCE TO RELATED APPLICATIONS

This application claims the benefit under 35 U.S.C. Section 119(e) of co-pending U.S. Provisional Patent Application Ser. No. 61/615,310, filed on Mar. 25, 2012, entitled “A MODULAR STRATEGY FOR INTRODUCING END-GROUP FUNCTIONALITY INTO CONJUGATED COPOLYMERS” the contents of which are incorporated herein by reference.

### FIELD OF THE INVENTION

The invention relates to polymer synthesis. More particularly, this invention relates to the synthesis of conjugated polymers having functional end groups.

### BACKGROUND OF THE INVENTION

A new generation of electronic devices including light-emitting diodes, field-effect transistors and photovoltaic cells as organic photovoltaics (OPVs) and organic light-emitting transistors (OLETs) is being fabricated using organic semiconductors as their active components. Conjugated polymer are useful in these devices as they combine the electrical properties of semiconductors with the mechanical properties of plastics. Moreover, these materials can be processed inexpensively by techniques such as spin-coating and ink jet printing. For this reason, they are finding applications in optoelectronic devices such as plastic light-emitting diodes (LEDs) and photovoltaic cells. Because conjugated polymers can be designed to form active layers in these types of electronic devices, these polymers provide promising materials for optimizing the performance of existing devices as well as the development of new devices.

Devices in which conjugated polymers can significantly improve function include organic photovoltaics. For example, in the last decade, the performance of polymer:fullerene bulk heterojunction (BHJ) organic photovoltaic devices has reached ˜9%. This improvement was achieved through the development of p-type low bandgap polymers in combination with a better understanding of control of the active layer morphology (see, e.g. Peet et al., Nat. Mater.2007, 6, 497; van Bavel et al., J. Adv. Funct. Mater. 2010, 20, 1458; and Brabec et al., Adv. Mater. 2010, 22, 3839). The active layer in BHJs comprises a random interpenetrating donor/acceptor network in bulk heterojunction OPVs. Annealing processes and additives of high boiling point solvent are found to produce nanostructured domain morphologies required for high power conversion efficiencies (PCEs) (see, e.g. Liang et al., Adv. Mater. 2010, 22, E135).

There is a need in the art for methods that allow artisans to synthesize conjugated polymer compositions having tailored functional properties.

### SUMMARY OF THE INVENTION

As discussed in detail below, we show that functional groups can be coupled to the ends of conjugated polymers in a manner that allows them to modulate one or more properties of these compositions. The methods and materials disclosed herein can, for example, be used to modulate the morphology of conjugated polymer blocks, and to provide these compositions with new or enhanced optical or electrical properties. Conjugated polymers having these properties are useful in a wide variety of applications.

Typical embodiments of the invention include methods for synthesizing conjugated polymers having an end group that contributes a selected function to the conjugated polymer. As discussed in detail below, this method typically comprises forming a reaction mixture of a monomer compound AA, wherein A comprises a first moiety selected for its ability to form a covalent bond in the polymer chain, a monomer compound BB, wherein B comprises a second moiety selected for its ability to form a covalent bond in the polymer chain, and an end capping compound (typically a polymer itself or a small molecule). In this methodology, the end capping compound is selected to comprise a functional group having an ability to modulate a property of the reaction product (e.g. an optical or electrical property), in combination with a reactive group selected for its ability to react with these monomers so that the functional group is coupled to an end of the polymer. In these methods, the monomer compound AA, the monomer compound BB and the end capping compound are combined under reaction conditions that allow the monomer compound AA and the monomer compound BB to polymerize and form a polymer while simultaneously allowing the end capping compound to react with these monomers, so that the conjugated polymer having the end group with the selected function is made. In certain embodiments of the invention, end-functionalized conjugated polymers can be synthesized in a single step from a stoichiometric mixture of components.

In illustrative embodiments of the invention, a functional group is selected for its ability to modulate a charge transport property of the conjugated polymer, and/or a light absorption property of the conjugated polymer and/or the morphology of the conjugated polymer and/or the miscibility of a conjugated polymer. In some embodiments of the invention, artisans can utilize an end capping compound having a functional group that modulates a specific electrical property of the conjugated polymer (e.g. a functional group that exhibits an electron or hole mobility >10⁻⁵ cm²/Vs). In other embodiments of the invention, artisans can utilize an end capping compound having a functional group that modulates a specific optical property of the conjugated polymer (e.g. a functional group that exhibits light absorption coefficients larger than 10⁴ cm⁻¹ in visible/NIR wavelength range in the solid state). In certain embodiments of the invention, the monomer compound AA, the monomer compound BB and the end capping compound are selected to form an all conjugated polymer that self assembles into a phase-separated microstructure comprising donor and acceptor domains. Optionally in embodiments of the invention, the components of the reaction mixture are selected to produce a conjugated polymer having a morphology where donor and acceptor blocks of phase-separated structures are formed to be of a length scale necessary for efficient exciton dissociation (e.g. about 10-20 nanometers).

As discussed below, a large number of different monomeric compounds and methods for using these monomers to form conjugated polymers are known in the art. The reactive properties of a large number of monomeric compounds used to form polymers are further known in the art, properties that allow artisans to identify end capping compounds that can react with these monomers, for example so as to introduce a functional group. This state of the art in polymer technology allows artisans to adopt a modular approach to making the conjugated polymers according to the methodology disclosed herein. In specific illustrative non-limiting embodiments of the invention discussed below, AA monomers can be selected from a group consisting of di-stannyl-aryl or di-borane-aryl monomers, BB monomers can be selected from a group consisting of di-halide, di-triflate or di-tosylate substituted monomers and the end capping compound functional group can be selected from a group consisting of a polythiophene containing end group, or a mono-brominated perylene diimide (PDI).

Embodiments of the invention also include conjugated polymers made by the methods disclosed herein. For example, one embodiment of the invention is a conjugated polymer comprising F-(AA-BB)n or F-(AA-BB)n-F, where F comprises an end capped functional group; and AA and BB comprise the polymerized monomers that form the polymer chain. Optionally, the conjugated polymers are all-conjugated block copolymers. In certain embodiments of the invention, these polymers have the ability to self-assemble into thermodynamically ordered nanostructures. Related embodiments of the invention include devices that utilize polymers made by the methods disclosed herein. For example, one embodiment of the invention includes devices comprising a conjugated polymer comprising EndCap-(AA-BB)n or EndCap-(AA-BB)n-EndCap, wherein the polymer has an end capped functional group that provides charge transporting and/or light absorption properties. Optionally, the device is selected from a group consisting of light-emitting diodes, field-effect transistors and photovoltaic cells. In addition, certain embodiments of the invention include these conjugated polymers in combination with one or more device elements such as a silicon substrate (e.g. one adapted for use in a semiconductor).

Yet another embodiment of the invention is a polymerization system comprising a monomer compound AA, wherein A comprises a first moiety selected for its ability to form a covalent bond in a polymer chain, a monomer compound BB, wherein B comprises a second moiety selected for its ability to form a covalent bond in a polymer chain, and an end capping compound. In this system, the end capping compound comprises a functional group selected for its ability to modulate an optical property (e.g. light absorption) or electrical property (e.g. charge transport) of a polymer to which the functional group is conjugated; and a reactive group selected for its ability to react with monomer compound AA or monomer compound BB so that the functional group can be coupled to an end of the conjugated polymer. In certain embodiments, the polymerization system includes a solvent and/or a reaction vessel in which the monomers and end capping compound can be combined. Optionally, the polymerization system is in the form of a kit, for example one including a plurality of containers that the combination of reagents used to form the functionalized conjugated polymers of the invention. In one illustrative embodiment, the kit includes one or more reagents used to form polymers (e.g. monomers, end capping compounds, solvents and the like).

### BRIEF DESCRIPTION OF THE DRAWINGS

For a more complete understanding of the present invention, reference is now made to the following descriptions taken in conjunction with the accompanying drawing, in which:

FIG. 1 shows: (a) Synthesis of P3HT-Br; (b) the synthetic route towards P3HT-b-DPP BCPs; and (c) NMR spectra of P3HT-Br and P3HT-b-DPP. The regions shown in the boxes are highlighted in the inset for clarity.

FIG. 2 shows: (a) GPC results of P3HT-Br (8 k) and P3HT-b-DPP BCPs based on an RI detector; and (b) the GPC contour of P3HT₈₇-b-DPP₁₃based on a UV detector.

FIG. 3 GPC contours based on the UV detector: (a) P3HT₆₃-b-DPP₃₇ block copolymer; (b) P3HT(8 k); (c) TDPP; and (d) physical blending of P3HT and TDPP.

FIG. 4 shows: (a) UV-Vis spectra of P3HT₈₇-b-DPP₁₃ in solution and solid film; and (b) DSC for P3HT₈₇-b-DPP₁₃.

FIG. 5 shows the chemical structures of P3EHT-b-DPP, P3HT-b-DPPF, P3HT-b-T2NDI.

FIG. 6 shows J-V curve of 100% BCP device made by P3HT-b-DPPF.

FIG. 7 shows synthesis of low band gap conjugated polymers based on DPP repeating unit containing the n-type small molecule perylene diimide (PDI) at the chain ends.

FIG. 8 provides drawings of generic chemical structures useful in embodiments of the invention.

FIG. 9 provides drawings of illustrative examples of AA monomers.

FIG. 10 provides drawings of illustrative examples of BB monomers.

FIG. 11 provides drawings of illustrative examples of D-A copolymers.

FIG. 12 provides drawings of functional small molecules useful in embodiments of the invention.

FIG. 13 provides a drawing of a reaction occurring in Example 1.

FIG. 14 provides a drawing of a reaction occurring in Example 2.

FIG. 15 provides a drawing of a reaction occurring in Example 3.

FIG. 16 provides a drawing of a compounds formed by a process disclosed in Example 4.

FIG. 17 Provides drawings of a number of devices that can utilize conjugated polymers having an end group with a selected function. For example, in some embodiments of the invention, a functionalized conjugated polymer is disposed within the active layer of a photovoltaic device as shown in FIG. 17(a). In other embodiments of the invention, a functionalized conjugated polymer is disposed within the active layer of a transistor device as shown in FIG. 17(b). In other embodiments of the invention, a functionalized conjugated polymer is disposed within the active/emission layer of an organic LED as shown in FIG. 17(c).

### DETAILED DESCRIPTION OF THE INVENTION

Unless otherwise defined, all terms of art, notations and other scientific terms or terminology used herein are intended to have the meanings commonly understood by those of skill in the art to which this invention pertains. In the description of illustrative embodiments, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Conjugated polymers are organic macromolecules which consist at least of one backbone chain of alternating double and single-bonds. Due to the fact that the p_{z}-orbitals of the carbon atoms which forms the n-orbitals of the alternating double-and single-bonds mesomerize more or less, i.e. the single and double bonds becomes similar, double-bonds overlaps also over the single bonds. Moreover, the π-electrons can be easier moved from one bond to the other, making conjugated polymers one-dimensional semiconductors.

As discussed below, polymer chains and/or small molecules having selected functional properties can be coupled to the ends of conjugated polymers. Conjugated polymers having such well-defined, functional end groups provide a new class of materials with promising properties that make them useful, for example, in a variety of organic electronic applications. Recently, all-conjugated block copolymers (BCPs) have been pursued by several groups, reporting that all-conjugated BCPs based on poly(3-hexylthiophene)-b-poly(9,9-dioctylfluorene) and P3HT-b-PFTBTT can form the desired nano-scale phase-separated lamellar structures (see, e.g. Verduzco et al., Macromolecules 2011, 44, 530; and Mulherin et al., Nano Lett. 2011, 4846). To date, there are several examples with fully conjugated BCPs but relatively fewer examples with all-conjugated donor-acceptor (D-A) BCPs (see, e.g. Izuhara et al., Macromolecules 2011, 44, 2678; and Woody et al., Macromolecules 2011, 44, 4690). The paucity of examples can be mainly contributed to the synthetic challenges to achieve the conjugated D-A block structure.

The disclosure provided herein includes methods for the synthesis of well-defined conjugated polymers that can comprise a variety of functional end groups including both polymer chains and small molecules. In this context, the term “polymer” is used according to its art accepted meaning, namely a substance that has a molecular structure built up chiefly or completely from a large number of similar units bonded together. Similarly, the term “small molecule” as used herein refers to a low molecular weight (typically <800 Daltons) organic compound that, when attached to the end of a polymer, can serve as a modulator of the material characteristics of that polymer.

As discussed in detail below, in exemplary embodiments of the invention, Stille-coupling polymerization reactions using the polythiophene and AA+BB monomer approach can be used to produce conjugated Donor-Acceptor (D-A)BCPs. In this scheme, A and B represent different type of reacting sites. As one working example, we teach the synthesis and characterization of the conjugated Donor-Acceptor BCPs, regioregular poly(3-hexylthiophene)-block-poly(diketopyrrolopyrrole-terthiophene), P3HT-b-DPP. In this block copolymer system, the P3HT segment serves as the electron donor, and the poly(diketopyrrolopyrrole-terthiophene) segment as the electron acceptor. One advantage of this method is its modularity and simplicity to prepare the AA/BB monomers. Moreover, this route allows artisans to create tailored energy gaps of BCPs, for example by varying the AA/BB monomer chemistry. In addition, this strategy is synthetically straight-forward and provides high-purity block copolymer on a reasonable scale.

A typical strategy for forming the polymeric compounds of the invention is to carry out the poly-condensation (e.g. a Suzuki- or Stille-coupling) polymerization with the AB-type monomers and bromine-terminated P3HT, where “A” and “B” represent different type of reacting sites. For example, A could be a trialkylstannyl or a boronic ester, and B could be a halide, triflate or a tosylate. In this context, we call a monomer the molecular structure of which is A-P—B an AB-type monomer and A-P-A and B-Q-B an AA-type and BB-type monomer, respectively, where P and Q represent bi-valent pi-conjugated organic moieties. A and B are reactive groups that form a chemical bond after reaction. A-P—B monomers can be used to generate a polymer A-P—X—P—X— . . . -P—B (we designate this polymer (AB)n), where X is a linker group or a direct bond formed by the reaction between A and B, and mixture of A-P-A and B-Q-B monomer generates A-P—X-Q-X— . . . (we designate this polymer (AA-BB)n). Typically however, the preparation of such asymmetrical AB-type monomers is problematic because of the synthetic challenge in preparing the AB-monomer with two different reacting sites, especially when the AB-monomer is used for acceptor moiety, which generally contains heteroaromatic units (e.g. pyridine, quinoxaline, quinolone or thienopyrazine). The preparation of A-B type monomer can limit the simplicity and preparation of n-type polymers.

One straight-forward methodology of the invention employs the Stille-coupling polymerization of AA and BB monomers in the presence of an end function group with a mono reacting site A or B. In typical embodiments of the invention, end-functional conjugated polymers can be synthesized in a single step from a mixture of the three components. For the case of all-conjugated BCPs, polythiophene containing mono reacting site at one chain end can be used as the chain capping agent. Due to the access of polythiophene type synthesis, any polythiophene derivatives, polyfurane derivatives and polyseleophene derivatives can be introduced into conjugated polymers. By using the synthetic methods disclosed herein, (AA-BB)n polymers can be formed, where either of the ends or both of the ends of the polymer chain are capped with the functional end cap group, like EndCap-(AA-BB)n or EndCap-(AA-BB)n-EndCap. In the case of EndCap-(AA-BB)n polymers, the other end can be capped with a different end cap group with or without functionality. The end-functionalized polymers can be used for the active materials for photovoltaic devices or used as additives. In either case, the synthetic process of this invention is useful because it is simple and low-cost and it gives purer materials than previously used methods.

Using the synthetic methods disclosed herein, we have discovered that end-functionalized polymers made of covalently linked polymers or small molecules can self-assemble into thermodynamically ordered structures. The nano-scale morphology of these end-functionalized polymers is driven by the phase separation of two covalently bound polymer blocks. These features not only make BCPs an appealing strategy for exerting control over active layer morphology in semiconducting polymer materials systems but also benefit the area of polymer-polymer solar cell device performance. Ideally, through the tailored design of BCPs consisting of donor and acceptor blocks phase-separated structures on the length scale necessary for efficient exciton dissociation (˜20 nm), but also efficient charge transport can be produced. Therefore, the development of all-conjugated donor-acceptor (D-A) BCPs with (a) sufficient solubility to enable solution processing, (b) strong and broad absorption across the solar spectrum, and (c) a large free charge carrier mobility for facile charge transport is of great significance in this technology.

A typical embodiment of the invention is a method for making a conjugated polymer having an end group with a selected function. As discussed in detail below, this method typically comprises forming a reaction mixture of a monomer compound AA, wherein A comprises a first moiety selected for its ability to form a covalent bond in the polymer chain, a monomer compound BB, wherein B comprises a second moiety selected for its ability to form a covalent bond in the polymer chain, and an end capping compound (typically a polymer itself or a small molecule). In this methodology, the end capping compound is selected to comprise a functional group having an ability to modulate a property of the reaction product (e.g. an optical or electrical property); and a reactive group selected for its ability to react with monomer compound AA or monomer compound BB so that the functional group is coupled to an end of the polymer. In some embodiments of the invention, the end capping compound reactive group reacts with A or B on the monomers. In certain embodiments of the invention, the end capping compound reactive group comprises A or B. In these methods, the monomer compound AA, the monomer compound BB and the end capping compound are combined so as to allow the monomer compound AA and the monomer compound BB to polymerize and form a polymer while simultaneously allowing the end capping compound to react, so that the conjugated polymer having the end group with the selected function is made. In some embodiments of the invention, the method comprises adding a second end capping compound to the reaction mixture, wherein the second end capping compound comprises a second functional group selected for its ability to modulate an optical or electrical property of the conjugated polymer; and a reactive group selected for its ability to react with monomer compound AA or monomer compound BB so that the second functional group is coupled to an end of the conjugated polymer.

Embodiments of the invention allow artisans to generate conjugated polymers that are coupled to a variety of moieties that provide selected functional properties. In typical embodiments of the invention, the functional group is selected for an ability to modulate the morphology or miscibility of a conjugated polymer and/or to modulate a charge transport property of the conjugated polymer, and/or to modulate a light absorption property of the conjugated polymer. For example, in some embodiments of the invention, artisans can utilize an end capping compound having a functional group that exhibits an electron or hole mobility >10⁻⁵ cm²/Vs. In other embodiments of the invention, artisans can utilize an end capping compound having a functional group that exhibits light absorption coefficients larger than 10⁴ cm⁻¹ in visible/NIR wavelength range in the solid state.

Embodiments of the invention include all-conjugated block copolymers (BCPs). All-conjugated block copolymers constitute a special type of end functional polymers, one where the end group is itself another polymer chain. Importantly, embodiments of these unique BCPs have the ability to self-assemble into thermodynamically ordered nanostructures. For this reason, donor-acceptor BCPs provide can be used in various strategies for controlling the active layer morphology in apparatuses such as organic photovoltaic devices. Additionally, all-conjugated BCPs allow a more effective control over phase separation between donor and acceptor components (as compared to two-component systems), while simultaneously ensuring a domain spacing on the order of the excitation diffusion length (e.g. 10-20 nm). In certain embodiments of the invention, the monomer compound AA, the monomer compound BB and the end capping compound are selected to form an all-conjugated polymer that self assembles into a phase-separated microstructure comprising donor and acceptor domains.

A number of monomeric compounds and methods for using these monomers to form conjugated polymers are known in the art. See, for example, Conjugated Polymers: Processing and Applications (Handbook of Conducting Polymers, Third Edition) 2012, Terje A. Skotheim and John Reynolds (Eds); Design and Synthesis of Conjugated Polymers 2012, Mario Leclerc and Jean-Francois Morin (Eds); and Conjugated Polymer and Molecular Interfaces: Science and Technology for Photonic and Optoelectronic Applications 2009, Jean-Jacques Pireaux (Author). Because the reactive properties of these monomeric compounds are further known in the art, artisans can readily identify end capping compounds that can react with these monomers, for example so as to allow a functional group to be coupled to the polymer. This state of the art in polymer technology allows artisans to use the instant disclosure to adopt a modular approach to making the conjugated polymers disclosed herein, for example one where monomers and end capping compounds are selected to form a particular conjugated polymer in view of known chemical, electronic or optical properties.

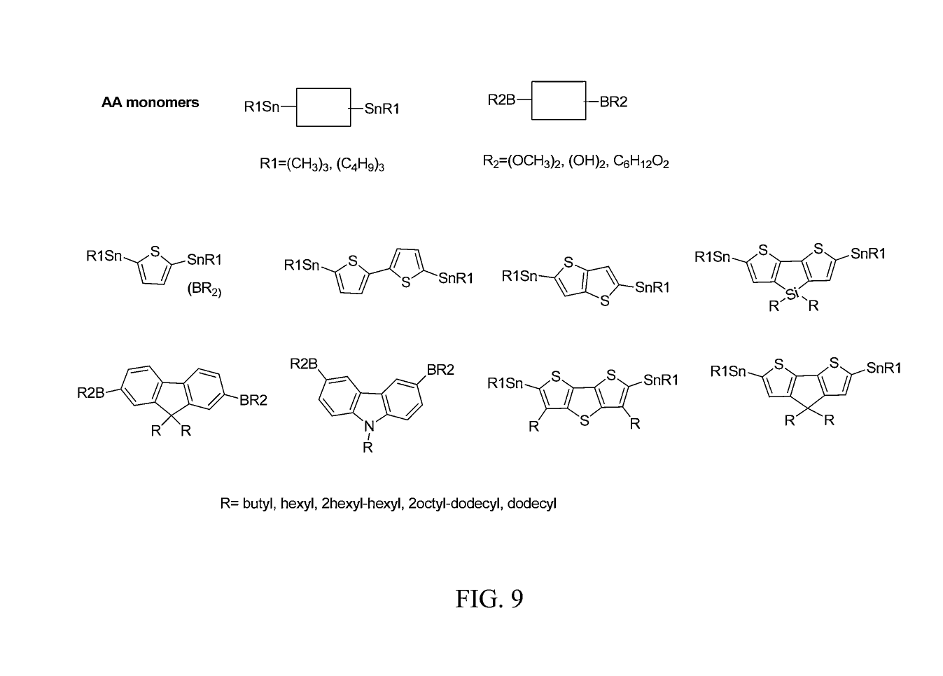

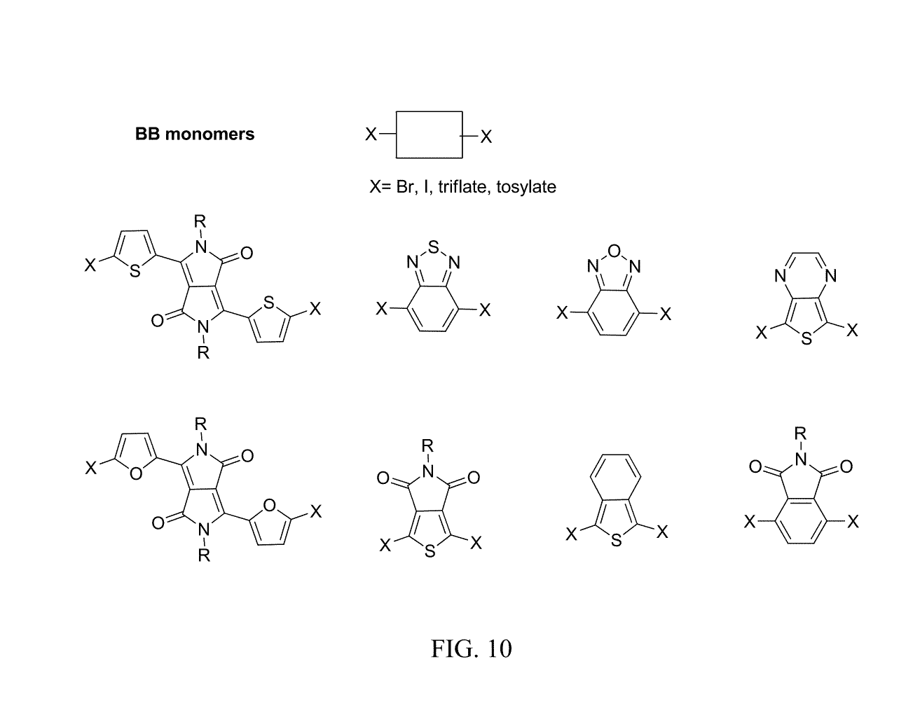

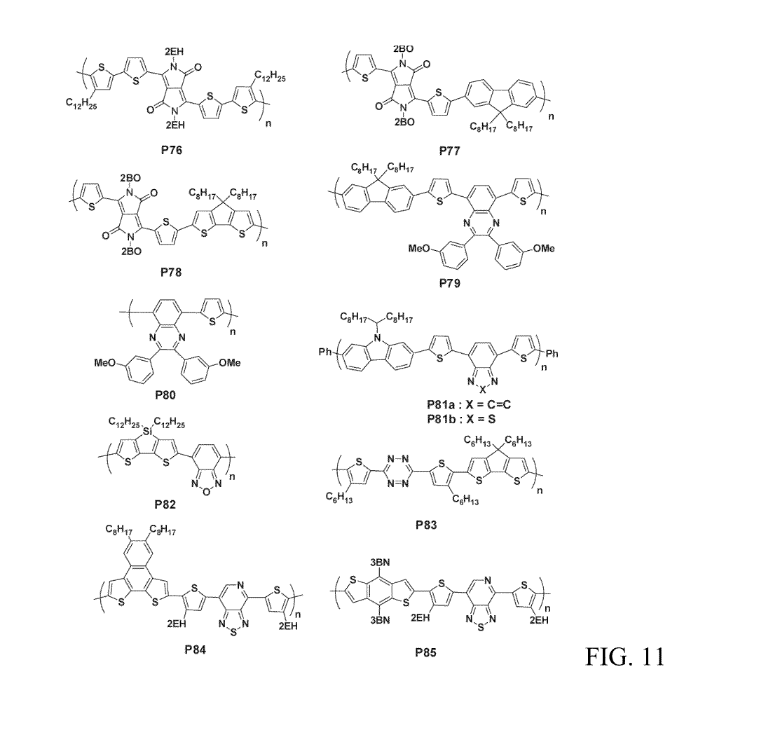

Illustrative examples of AA monomers and BB monomers useful in embodiments of the invention are shown in FIGS. 9 and 10. Additional illustrative examples of AA monomers that can be used in embodiments of the invention are described in Facchetti Chem. Mater. 2011, 23, 733; and Cheng et al., Chem. Rev. 2009, 109, 5868-5923. Specific examples of AA monomers include those having a di-Stannyl-phenyl unit or diborane-phenyl unit. These can include, but are not limited to molecules where each R is independently nothing or a substituted or non-substituted alkyl or alkoxy chain. In some embodiments, the substituted or non-substituted alkyl or alkoxy chain can be a C6-C30 substituted or non-substituted alkyl or alkoxy chain, (CH2CH2O)n (n=2˜0), C6H5, CnF(2n+1) (n=2˜20), or a combination of above. Examples of BB monomers that can be used in embodiments of the invention are described in Facchetti Chem. Mater.2011, 23, 733; and Cheng et al., Chem. Rev. 2009, 109, 5868-5923. Specific non-limiting examples of BB monomers include compounds with dihalide, di-triflate or di-tosylate substitution groups, including those having bromo-substitution and iodo substitutions, but are not limited to, where each R (see, e.g. FIGS. 9 and 10) is independently nothing or a substituted or non-substituted alkyl or alkoxy chain. In some embodiments, the substituted or non-substituted alkyl or alkoxy chain can be a C6-C30 substituted or non-substituted alkyl or alkoxy chain, (CH2CH2O)n (n=2˜20), C6H5, CnF(2n+1) (n=2˜20), or a combination of above. Illustrative examples of D-A copolymers are shown in FIG. 11. Additional examples of materials that can be used in embodiments of the invention are described in Cheng et al., Chem. Rev. 2009, 109, 5868-5923.

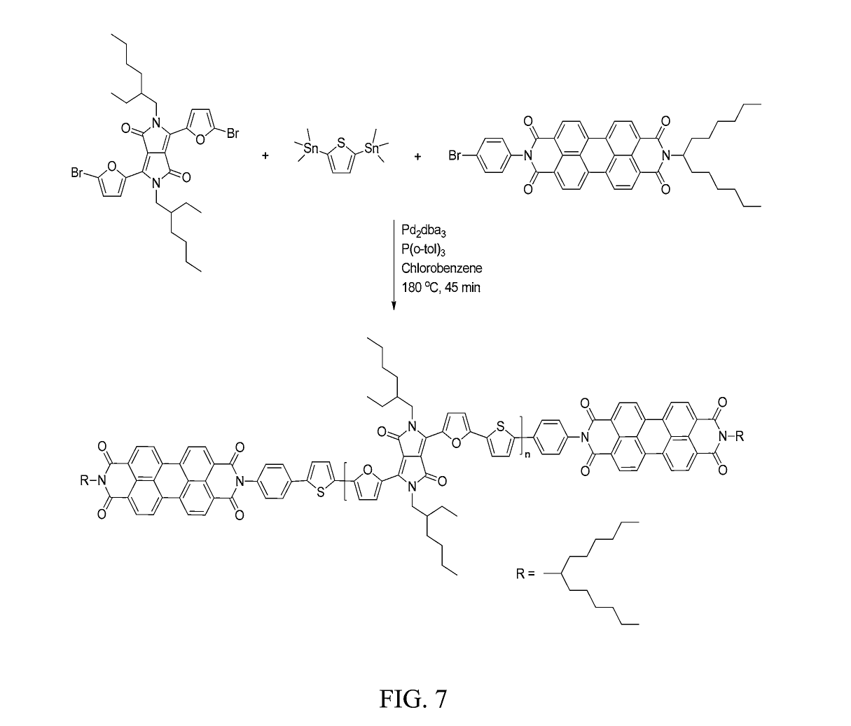

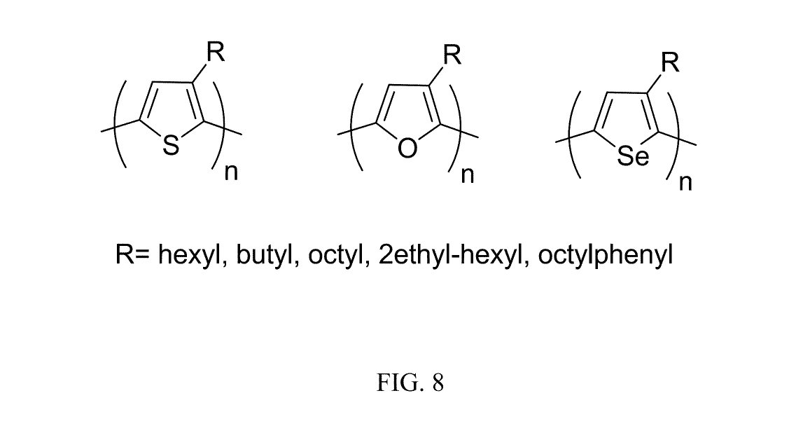

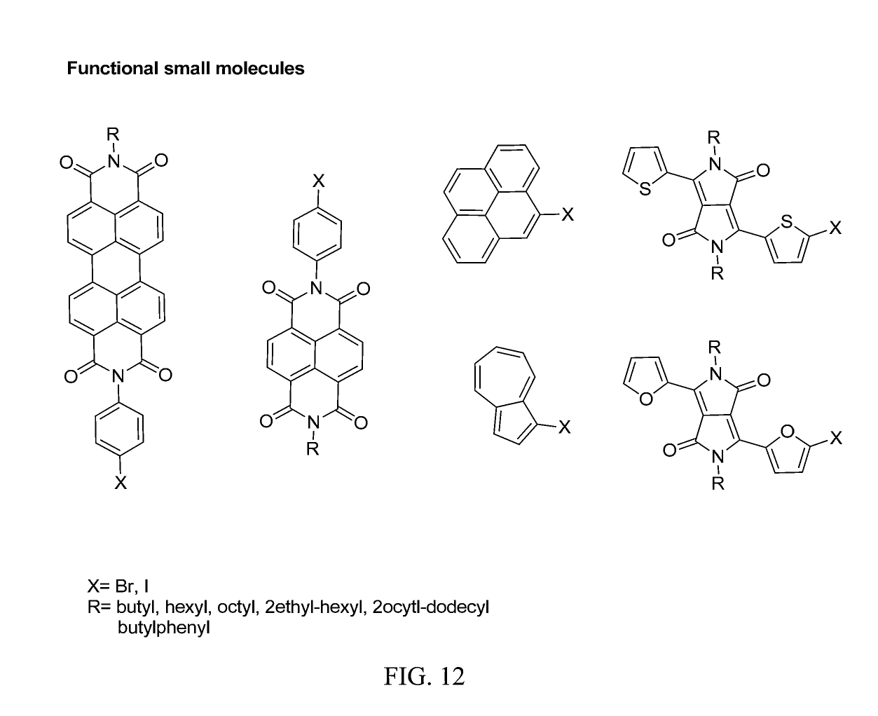

In typical embodiments of the invention, functional groups can comprise a polymer chain or a small molecule which is capable of modulating charge transport or light absorption. Here, we report two working examples of embodiments of the invention, ones where the end capping compounds are polythiophene (a compound which is useful to modulate semiconductor charge transport) or perylene diimide (PDI, a light absorption chromophore). In view of this data, those of skill in this art will understand that illustrative functional end groups with a mono reacting site include, but are not limited to, polythiophene containing end group, such as poly(3-hexylthiophene), poly(3-(2-ethylhexyl)thiophene), poly(3-octylthiophene); and mono-brominated perylene diimide (PDI) small molecule, such as the alkyl substituent on the imide N can comprise a general substituent R, wherein R comprises alkyl groups or aryl groups (see, e.g., FIG. 12). Additional illustrative light absorption molecules useful in embodiments of the invention are disclosed, for example, in Mishra et al., Angew. Chem. Int. Ed. 2009, 48, 2474; Shirota et al., Chem. Rev. 2007, 107, 953-1010; and Li and H. Wonneberger, Adv. Mater. 2012, 24, 613-636. Functional groups can also include, for example, a wide variety of organic molecules having aryl-halide substitutions. FIG. 8 provides drawings of some generic structures for functional polymers, which have carrier mobility. The R substitution group can include not only alkyl substituted group, but also aryl substituted group, such as hexyl, butyl, 2ethyl-hexyl, and octylphenyl and the like. In the working example of methods for introducing small molecules into polymers, we demonstrate how to introduce the light-absorbing choromophore perylene diimide (PDI) as shown in FIG. 7. In such embodiments, the alkyl substituent on the imide N can be a general substituent designated “R”, including not only alkyl groups (such as hexyl, butyl, octyl, 2octyl-hexyl) but also aryl groups (such as octylphenyl) and the like. This modular synthetic method provides access to a variety of block copolymers and the installation of other functional end groups onto conjugated polymers. This method results in well-defined, highly pure materials and simplifies many tedious synthetic procedures previously employed to synthesize functional conjugated polymers having desired material properties. For example, in certain embodiments of the invention, the monomer compound AA, the monomer compound BB and the end capping compound are selected to form an all-conjugated polymer that self assembles into a phase-separated microstructure comprising donor and acceptor domains. In specific embodiments of this invention, the donor and acceptor domain exhibit a characteristic length scale of about 10-20 nanometers

Embodiments of the invention also include conjugated polymers made by the methods disclosed herein. For example, embodiments of the invention include a conjugated polymer comprising F-(AA-BB)n or F-(AA-BB)n-F, where F comprises an end capped functional group; and AA and AB comprise the polymerized monomers that now form the polymer chain. Embodiments of the invention include methods of making and purifying the conjugated polymer having the functionalized end group. In one embodiment of the invention, the polymer is made according to a method disclosed herein and then purified by a process comprising soxhlet extraction. In another embodiment, the polymer is made according to a method disclosed herein and then purified by a process consisting essentially of: (a) precipitation; and (b) filtration (i.e. in the absence of soxhlet extraction).

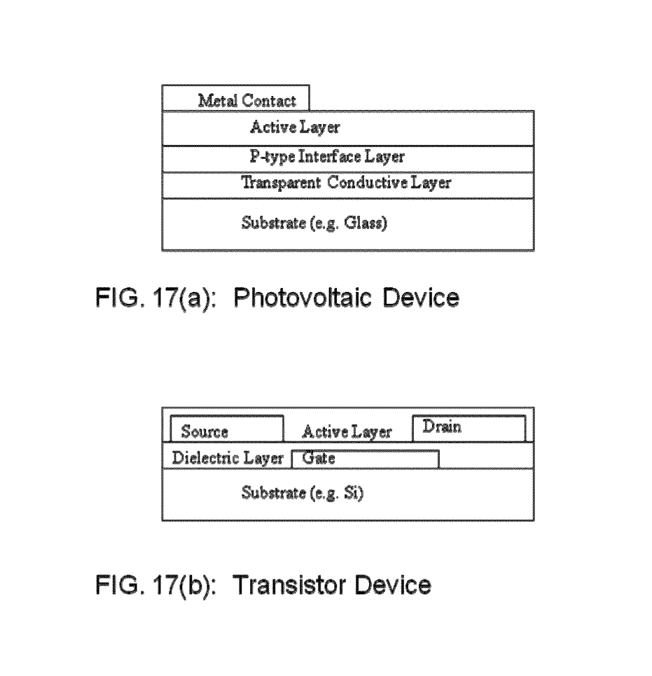

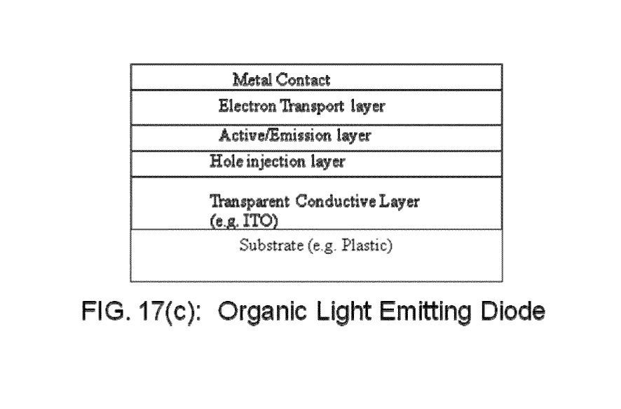

Other embodiments of the invention include devices that utilize polymers made by the methods disclosed herein. For example, embodiments of the invention include devices comprising a conjugated polymer comprising EndCap-(AA-BB)n or EndCap-(AA-BB)n-EndCap, wherein the polymer has an end capped functional group that provides charge transporting and/or light absorption properties. Optionally, the device is selected from a group consisting of light-emitting diodes, field-effect transistors and photovoltaic cells. In addition, certain embodiments of the invention include these conjugated polymers in combination with one or more device elements such as a silicon substrate (e.g. one adapted for use in a semiconductor). In some embodiments of the invention, a functionalized conjugated polymer is disposed within the active layer of a photovoltaic device as shown in FIG. 17(a). In other embodiments of the invention, a functionalized conjugated polymer is disposed within the active layer of a transistor device as shown in FIG. 17(b). In other embodiments of the invention, a functionalized conjugated polymer is disposed within the active/emission layer of an organic LED as shown in FIG. 17(c).

In certain embodiments of the invention, the device is a polymer-based photovoltaic device. Polymer-based photovoltaics represent potentially low-cost, solution-processable devices for achieving sustainable energy generation. The optimal polymer-fullerene bulk heterojunction photovoltaic relies on a phase-separated microstructure in which domains of each component exist to allow for exciton dissociation at the interface and transport of each free electron (hole) through the n-type (p-type) domain to the cathode (anode). In view of this, certain embodiments of the invention, the monomer compound AA, the monomer compound BB and the end capping compound are selected to form a conjugated polymer that can assemble into a phase-separated microstructure in which domains of each component exist to allow for exciton dissociation at the interface and transport of each free electron (hole) through the n-type (p-type) domain to the cathode (anode). Optionally in these embodiments, donor and acceptor blocks of phase-separated structures are formed to be of a length scale necessary for efficient exciton dissociation (e.g. about 10-20 nanometers). This route further allows artisans to create tailored energy gaps of BCPs, for example by varying the AA/BB monomer chemistry.

Yet another embodiment of the invention is a polymerization system comprising a monomer compound AA, wherein A comprises a first moiety selected for its ability to form a covalent bond in a polymer chain, a monomer compound BB, wherein B comprises a second moiety selected for its ability to form a covalent bond in a polymer chain, and an end capping compound. In this system, wherein the end capping compound comprises a functional group selected for its ability to modulate an optical (e.g. light absorption) or electrical property (e.g. charge transport) of a polymer to which the functional group is conjugated; and a reactive group selected for its ability to react with monomer compound AA or monomer compound BB so that the functional group can be coupled to an end of the polymer. In certain embodiments, the polymerization system includes a solvent in which the monomers and end capping compound can be combined in the reaction mixture and/or a reaction vessel in which the monomers and end capping compound can be combined. Optionally, the polymerization system is in the form of a kit, for example one including a plurality of containers that hold the reagents used to form the polymers. In one illustrative embodiment, the kit includes a plurality of reagents used to form polymers (e.g. monomers, end capping compounds, solvents and the like).

The methods disclosed herein can be used to modulate the material properties of conjugated polymers in order to, for example, facilitate their use in organic devices. For example, using the methods and materials disclosed herein, functional end groups can be used to adjust the miscibility of a middle conjugated polymer with other donor or acceptor components, for example within the morphology of the bulky hetero junction (BHJ) device. Briefly, a proper morphology of the phase separated BHJ materials is critical to the performance of solar cells. To provide the pathways that carry the photogenerated charge carriers to the electrodes, ideal morphology is an interpenetrating network by donor and acceptor with minimum amount of isolated domains. The characteristic length scale of each phase needs to be at the order of 10-20 nm, close to the diffusion length of the excitons. The functional end polymers or small molecules which covalently attached to the middle polymer chain but have different miscibility with both the middle chain and other donor or acceptor components can be used to induce and stabilize the proper BHJ device morphology.

Functional end groups can also be used, for example, to increase the light absorption of the middle conjugated polymer. The efficiency of a photovoltaic device is calculated by its open circuit voltage, short circuit current and fill factor (η=Voc*Jsc*ff). The short circuit current is propositional to the device photocurrent which is determined by both the fractional number of absorbed photons in the active layer and the IQE defined by the fraction of collected carriers per absorbed photon. Device current output and efficiency can be increased by incorporating chromophores with very strong light absorption as the functional end groups of the conjugated donor or acceptor polymers.

Functional end groups can also be used, for example, to provide charge transporting property. The exciton diffusion length highly depends on the material's charge mobility. Balanced electron/hole mobility is another critical requirement for high device efficiency. The functional end groups with good electron and/or hole mobility can facilitate the charge separation between donor and acceptor domains and charge transport in these domains. Functional end groups can also be used, for example, to adjust the energy level of the middle conjugated polymer chain, which again can facilitate the charge separation between donor and acceptor domains in the BHJ device.

### Illustrative Working Embodiments of the Invention

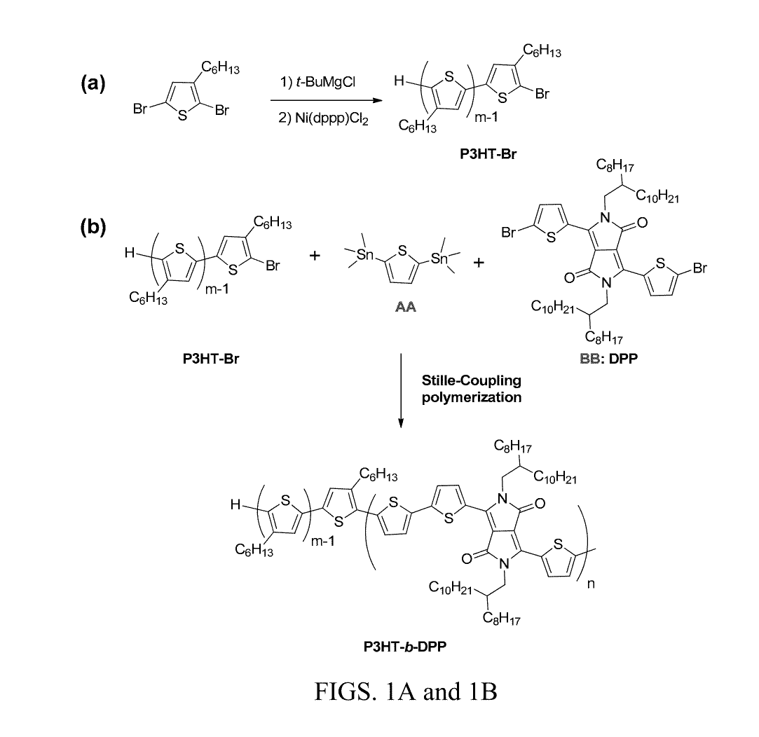

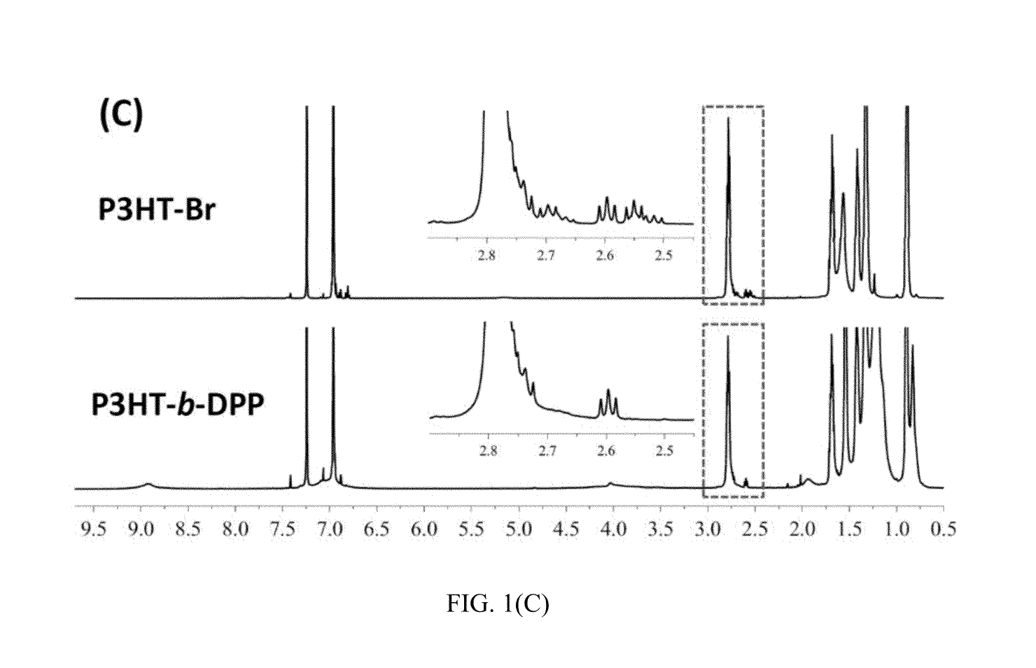

Using the disclosure presented herein, artisans can make and use a wide variety of conjugated polymer molecules. In working examples, two segments of P3HT and TDDP polymers are covalently bound and synthesized through poly-condensation polymerization following the AA/BB approach. The P3HT in this embodiment was first prepared by Grignard metathesis polymerization following the procedure developed by McCullough and coworkers as shown in FIG. 1(a) (see, e.g. Iovu et al., Macromolecules 2005, 38, 8649). This method leads to well-defined mono-bromo-terminated P3HT referred to as P3HT-Br with a molecular weight distribution of ˜1.1. The monomer of the fused ring dibromo-1,4-diketopyrrolo[3,4-c]pyrrole (DPP) can be prepared by three steps, as described previously (see, e.g. Li et al., Adv. Mater. 2010, 22, 4862; and Woo et al., J. Am. Chem. Soc. 2010, 132, 15547). In this embodiment of the invention, the block copolymers were then synthesized in one step with the mixture of 1 equiv. DPP, 1 equiv. bis(trimethylstannyl)-thiophene, and a varying amount (5%-20%) of P3HT-Br under microwave irradiation using Pd₂(dba)₃/P(o-tolyl)₃ as a catalyst. The reagent mixtures are irradiated under the microwave condition to synthesize the block copolymers as shown in FIG. 1(b). The BCPs can be simply purified by soxhlet extraction and characterized by NMR and GPC.

Analysis of the NMR spectrum can be used to provide useful information about the formation of block copolymer. FIG. 1(c) shows ¹H NMR spectra of P3HT-Br and P3HT-b-DPP in CDCl₃. Firstly, the NMR spectra of P3HT-Br and P3HT-b-DPP present one piece of evidence about the two blocks being covalently bound. The main aromatic hydrogen of P3HT-Br shows a large peak at ˜2.8 Hz. Two small triplet peaks appear at 2.5-2.6 Hz, representing the aromatic hydrogen of the terminal bromo-thiophene and the terminal hydrogen-thiophene, respectively (see, e.g. Verswyvel et al. Macromolecules 2011, 44, 9489). After P3HT-Br reacts with DPP and bis(trimethylstannyl)-thiophene to form the BCP, the main aromatic hydrogen of P3HT-b-DPP does not change (˜2.8 Hz), but there is only one small triplet peak at 2.6 Hz, representing the aromatic hydrogen of the terminal hexyl thiophene. The NMR results indicate the efficient transformation of bromo-thiophene from P3HT-Br and imply successful block copolymer formation. Secondly, the relative size of the two blocks can be determined from ¹H spectra of P3HT-b-DPP, according to the integration of the aromatic hydrogen peak of polythiophene (2.8 Hz) and the peak corresponding to the thiophene adjacent to the diketopyrrolopyrrole (9.0 Hz). The molecular weights, PDIs, and m/n ratios are summarized in Table 1.

The size of the polythiophene can be controlled by varying the reaction time, according to the McCullough procedure. The second polymer block of P3HT-b-DPP can be modulated in relative size by controlling the concentration of P3HT-Br. With the total number of stannyl-reacting site thiophene and bromo-reacting site DPP monomers held equal, varying amounts of P3HT are introduced in controlling the molecular weight of the polymer. High molecular weight BCPs can be synthesized by reducing the amount of P3HT-Br from 20% to 6%, while a larger molar amount of P3HT-Br results in lower molecular weight BCPs, as the GPC data demonstrates. In addition to demonstrating this strategy, we not only synthesized the BCPs with (Mₙ=8100) P3HT, but also used the longer (Mₙ=13600 and 21500) P3HT-Br for diblock formation. Interestingly, the poly-condensation polymerization usually results in large PDIs of ˜3. However, in this study the GPC results indicate formation of materials with PDIs of ˜1.9, which implies that our samples have fairly uniform molecular weight distributions.

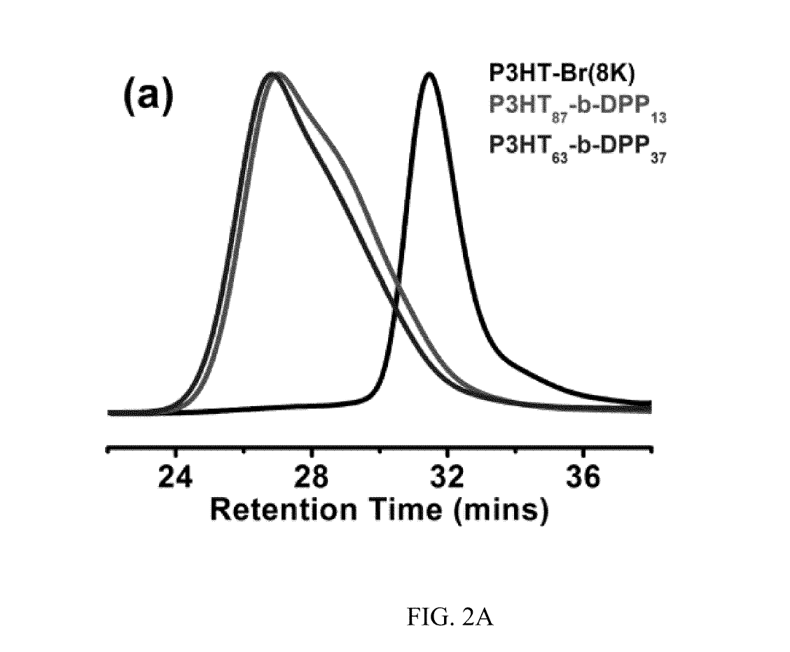

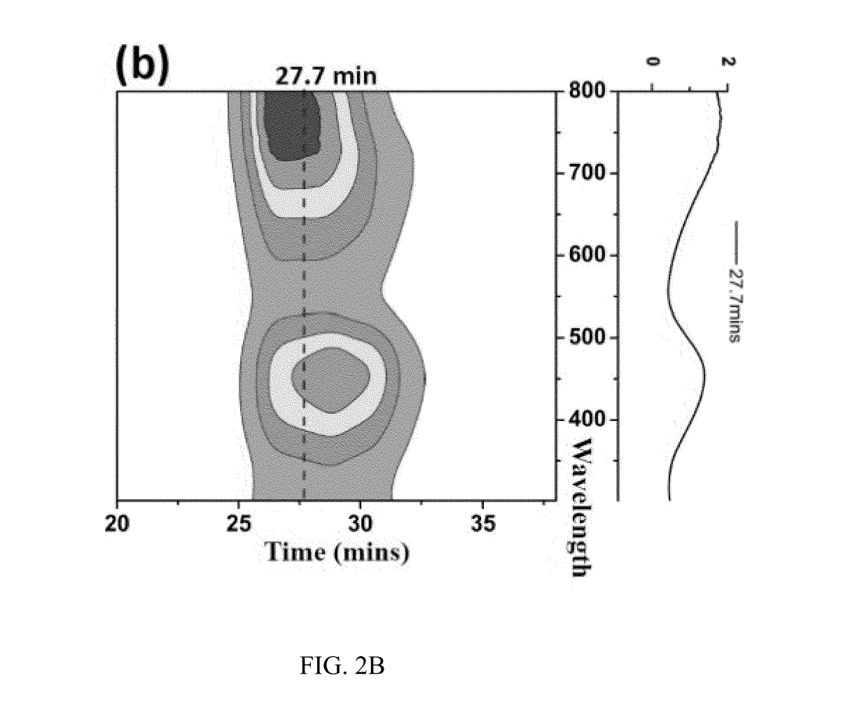

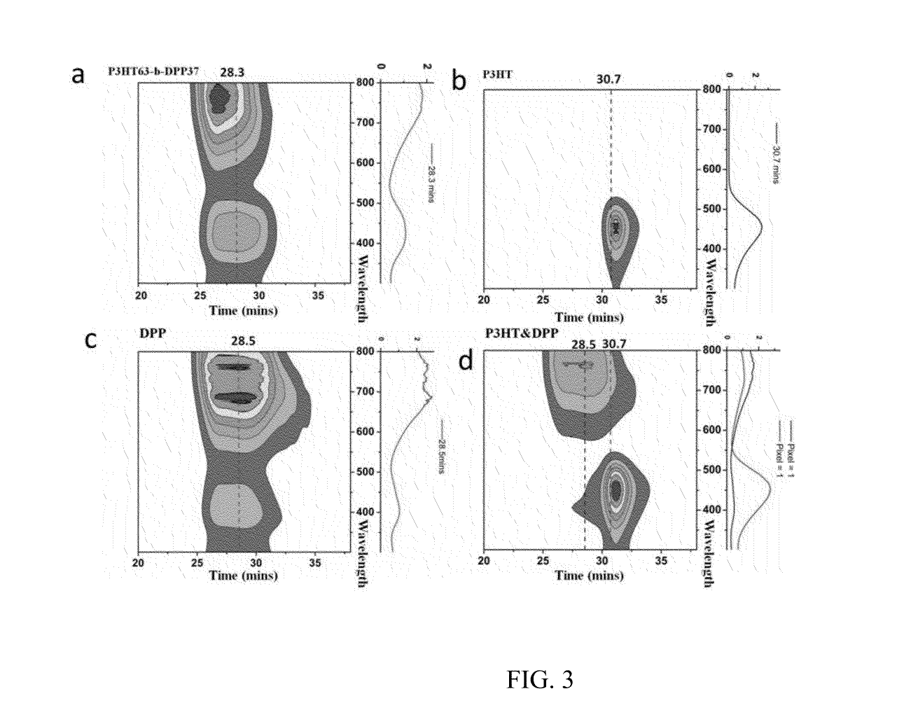

The strategy towards BCPs following the AA/BB approach could potentially give side products such as residues of P3HT and TDPP homopolymers. However, the GPC results based on refractive index (RI) and UV detectors so that this is not a large problem and ease concerns about these impurities. The molecular weight and PDI of the polymers were measured by GPC and calculated using polystyrene standards. The GPCs are performed in chloroform and monitored by both detectors. FIG. 2(a) shows the GPC results of P3HT-Br (8 k) and two BCPs collected by the RI detector. The P3HT-Br and the P3HT-b-DPP BCPs have distinctly different retention times (32 min and 27 min, respectively).The P3HT₈₇-b-DPP₁₃ BCP has a number-average molecular weight, Mₙ, of ˜37 000 a.m.u.; the P3HT₆₃-b-DPP₃₇ BCP has a slightly higher Mₙ of ˜44 000 a.m.u. In investigating these spectra, one significant concern is the tailing shoulder from P3HT-b-DPP, which overlaps partially with P3HT-Br. The tailing shoulder originates from low molecular weight polymers, which could indicate either residual P3HT or the low-bandgap homopolymer of TDPP. In order to assess this concern, we used the GPC contour based on a UV detector to analyze the specific components of the block copolymers, as shown in FIG. 2(b). The GPC contour of P3HT-Br only shows one broad UV-Vis spectrum, ranging from 350-550 nm at 31 min (FIG. 3(b)). However, the BCP shows two components, absorbing from 350-550 nm and 550-800 nm, even at a retention time of 31 min, where the tailing shoulder partially overlaps with the P3HT-Br spectrum. This indicates that the block copolymer is of high purity, free of P3HT homopolymer contaminant. As a control, we analyzed a physical blend of P3HT homopolymer and TDPP homopolymer, which resulted in two separate peaks that do not have the two-component UV-Vis absorption.

TABLE 1
Molar ratios of repeat units, molecular
weights and PDIs of polymers.

| | Mole ratio of repeat | | | |
|---|---|---|---|---|
| | unit as determined by | Mₙ | M_{w} | |
| Polymer | ¹H NMR | [g/mol] | [g/mol] | PDI |
| P3HT-Br (8 k) | 100/0 | 8 100 | 8 700 | 1.07 |
| TDPP | 0/100 | 26 300 | 60 500 | 2.29 |
| P3HT(8 k)₈₇-b-DPP₁₃ | 87/13 | 37 200 | 69 400 | 1.86 |
| P3HT(8 k)₆₃-b-DPP₃₇ | 63/37 | 44 200 | 84 500 | 1.91 |
| P3HT-Br (14 k) | 100/0 | 13 600 | 15 500 | 1.13 |
| P3HT(14 k)₈₅-b-DPP₁₅ | 85/15 | 27 400 | 45 200 | 1.65 |
| P3HT-Br (21 k) | 100/0 | 21 500 | 26 900 | 1.24 |
| P3HT(21 k)₅₄-b-DPP₄₆ | 54/46 | 49 300 | 75 000 | 1.90 |

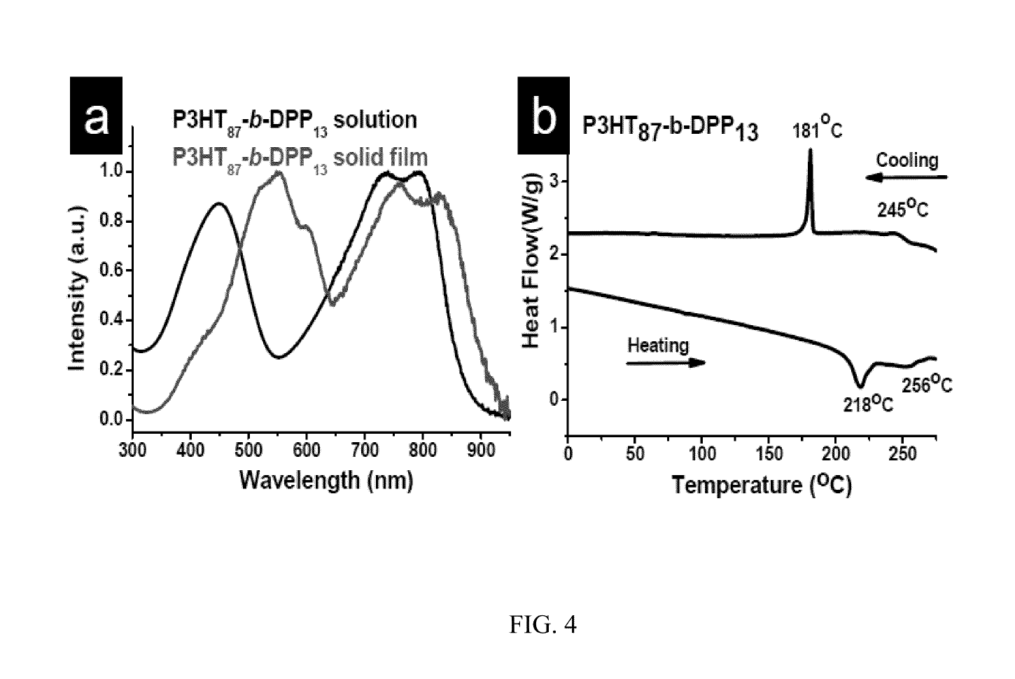

UV-Vis absorption spectra of P3HT-b-DPP were taken both in dichlorobenzene solution and in solid film (FIG. 4(a)). The film was spun-cast from a 5 mg mL¹ solution in dichlorobenzene. P3HT-b-DPP has broad absorption spectrum over the UV-visible region. Both the solution and film spectra exhibit two specific absorption peaks, resulting from two blocks of P3HT and DPP polymer. The film UV spectrum is red-shifted, as compared to the solution spectrum, especially for the absorption attributed to the P3HT block, indicating some block-specific aggregation behavior.

The thermal transition temperatures of the polymers were measured by differential scanning calorimetry (DSC). The DSC result of P3HT-Br (8 k) has a single endothermic peak on heating at 220° C. and a crystallization transition at 198° C. upon cooling. The TDPP homopolymer shows one single endothermic peak on heating at 252° C. The block copolymer, P3HT₈₇-b-DPP₁₃, has two melting points at 218° C. and 256° C. (FIG. 4(b)), where the low Tₘ corresponds to the P3HT block and the high Tₘ corresponds to the DPP polymer block. When the BCP is cooled, it shows the two crystallization transitions at 245° C. and 181° C. The ratio of enthalpy change for two block components can be related to the molar ratio of two blocks (m/n). In this case of P3HT₈₇-b-DPP₁₃, the P3HT has bigger integration area than DPP polymer block.

### Other Examples of Conjugated Block Copolymers

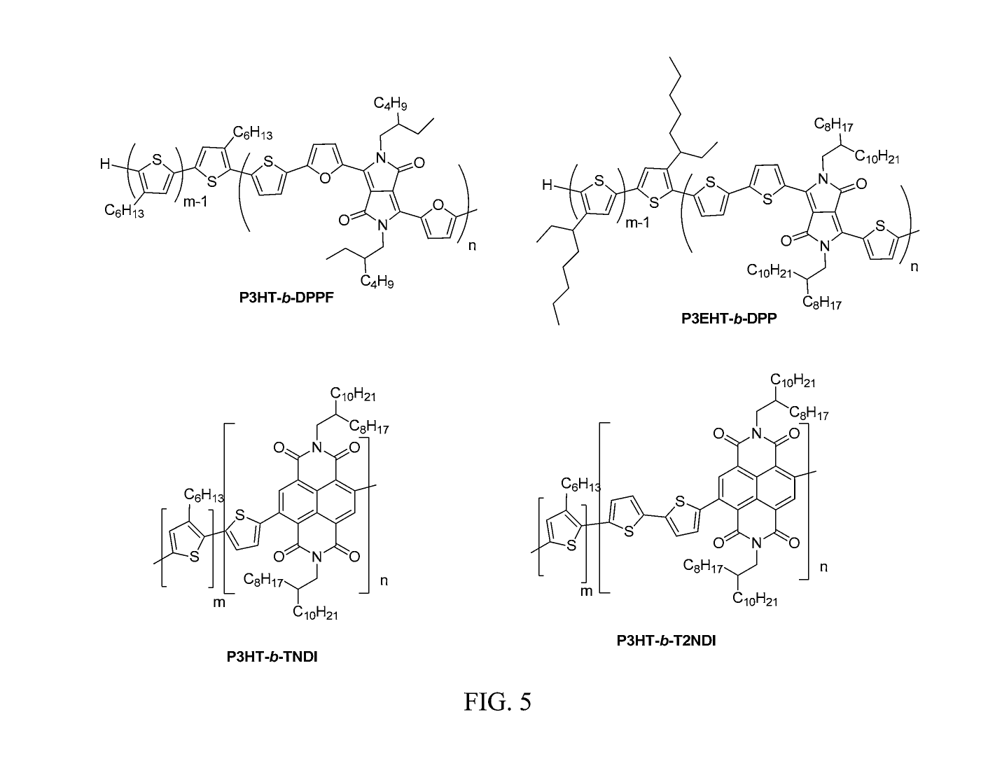

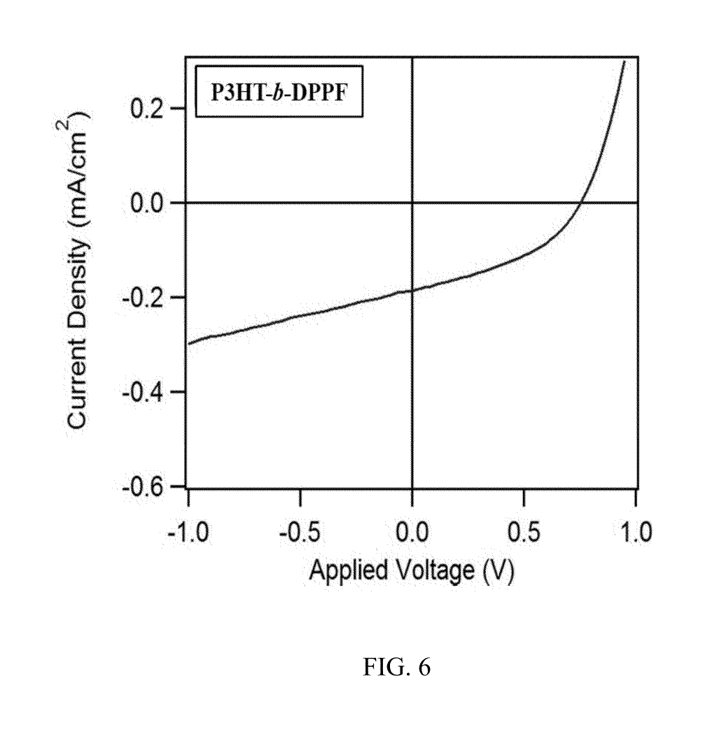

This strategy works not only for polythiophene derivatives, but also other AA/BB acceptor monomer. Following the same strategy, we can make a series of block copolymers, based on polythiophene derivatives, DPP type acceptor and NDI type acceptors. The block copolymer structures are shown in FIG. 5.

### Illustrative Applications OPV Devices

The initial polymer-polymer solar cells were fabricated based on two homopolymers of P3HT, DPPF and P3HT-b-DPPF block polymers, which did not use fullerene derivatives as electron transporting materials. The physical blending of two homopolymers device (0% BCP) shows the very low J_{sc}, FF and PCE. However, in the ternary system of P3HT, DPPF, and P3HT-b-DPPF, the device results were improved. Interestingly, with increased loading of BCP, the PCE drastically improves. For example, the PCE of device for 50% BCP is 5 times higher than that for 0% BCP. The block copolymer can act as surfactants and a compatibilizer in the ternary system.

The best result is the device of 100% BCP, which was made by single component of the P3HT-b-DPPF block copolymer. The best PCE is 0.07% (V_{oc}=0.49V, J_{sc}=0.33, FF=0.46). It's worth noting that the fill factor of polymer-polymer solar cell remains ˜0.46.

TABLE 2
Summary of polymer:polymer device data

| | | | J_{sc} | | | |
|---|---|---|---|---|---|---|
| | | | (mA | V_{oc} | | |
| Device | Component | Processing | cm⁻²) | (V) | FF | PCE |
| 0% BCP | P3HT + DPPF | As cast | 0.08 | 0.26 | 0.28 | 0.006 |
| | | 240° C. | 0.10 | 0.22 | 0.29 | 0.006 |
| 10% BCP | P3HT + DPPF | As cast | 0.11 | 0.52 | 0.31 | 0.017 |
| | P3HT-b-DPPF | 240° C. | 0.11 | 0.28 | 0.39 | 0.012 |
| 50% BCP | P3HT + DPPF | As cast | 0.15 | 0.61 | 0.44 | 0.042 |
| | P3HT-b-DPPF | 240° C. | 0.19 | 0.33 | 0.40 | 0.025 |
| 100% BCP | P3HT-b-DPPF | As cast | 0.19 | 0.76 | 0.41 | 0.060 |
| | | 240° C. | 0.33 | 0.49 | 0.46 | 0.074 |

### Other Examples of End-functionalized Copolymers Based on Small Molecules

A similar synthetic strategy can be employed to access well-defined conjugated polymers with functional small molecules located at the chain ends. For example, low band gap conjugated polymers with n-type electron conducting end groups can be prepared by Stille-coupling polymerization of AA and BB monomers in the presence of a mono-brominated perylene diimide (PDI) small molecule (FIG. 7). Here any small molecular with aryl-bromide (or iodide, triflate or tosylate) group can be introduced into conjugated polymers. In this case, the ratio of AA and BB monomers is varied and the mono-brominated PDI is incorporated so that the total number of aryl bromide groups is stoichiometric with aryl stannane groups in the reaction. Furthermore, highly pure polymers can be attained by a simple purification process involving precipitation and filtration through a short pad of silica gel, circumventing the need for Soxhlet extraction. Using this strategy, well-defined end-functional materials can be readily accessed with accurate control of both electronic and structural properties (e.g. molecular weights, etc).

TABLE 3
OPV device results for PDI-end-functional polymer

| Polymer | V_{oc} (V) | J_{sc}(mA cm⁻²) | FF | PCE (%) |
|---|---|---|---|---|
| DPPF (homopolymer) | 0.77 | 9.1 | 0.52 | 3.7 |
| PDI-DPPF-PDI | 0.77 | 10.0 | 0.55 | 4.2 |

Conjugated polymers containing well-defined functional end groups can be used as new hole conducting materials or as interfacial additives for bulk heterojunction polymer solar cells. Specifically, the end-functionalization of conjugated polymers can act to improve the electronic properties at the interface between donor and acceptor components in the bulk heterojunction resulting in more efficient charge transport and higher overall PCEs. For example, recent results demonstrate that OPV devices prepared using the PDI end-functionalized polymer, PDI-DPPF-PDI, have higher PCEs than devices made with the polymer without end-functional groups (Table 3). Specifically, the efficiency of devices prepared using the end-functionalized polymer as the sole p-type material is 14% higher than devices using the analogous polymer without end group functionality.

End-functionalized conjugated polymers have tremendous potential as electronically active additives for bulk heterojunction devices. The frontier energy levels of the polymer end groups can be readily engineered such that they are located in between those of the donor and acceptor components. Tuning this energy level alignment will have important implications in the design of high efficiency solar cells. This technique represents a promising strategy for enhancing the electronic properties at the donor/acceptor interface within the active layer and improving the overall properties of bulk heterojunction polymer solar cells.

### EXAMPLES

As disclosed herein, a variety of new polymer materials including donor-acceptor conjugated BCPs and end-functionalized conjugated polymers can be prepared using a modular synthetic route. This synthetic method allows BCPs with high purity to be easily prepared and purified. Furthermore, the self-assembly behavior of the novel BCPs has been characterized and can be controlled by the film annealing process. This synthetic strategy has been extended to the preparation of well-defined conjugated polymers with small molecule functional end groups. These polymers display promise as active materials in OPV bulk heterojunction devices both as novel hole conducting polymers and as electronically active additives to enhance the electronic properties at the donor/acceptor interface.

The following examples demonstrate how embodiments of the invention can include processes for producing conjugated polymers containing a variety of functional end groups, the process comprising performing coupling polymerization in the presence of AA monomer, BB monomer and a functional end group bearing either A or B type reacting site. Typically, the functional end group results in providing to the polymer charge transporting and/or light absorption properties.

### Example 1

### Synthesis of a P3HT-Br

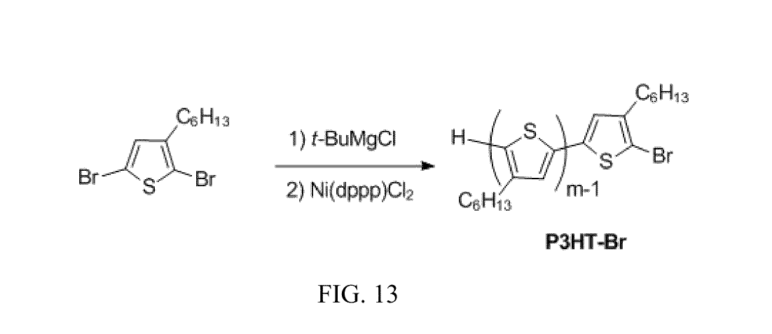

FIG. 13 provides a drawing of a reaction occurring in Example 1. In a dried Schlenk flask equipped for magnetic stirring, 2,5-dibromo-3-hexylthiophene (1.53 g, 4.71 mmol) in 50 mL dry THF was placed under protection gas. A solution of t-butylmagnesium chloride in THF (2.35 mL, 4.71 mmol, 2M) was added and the mixture was heated for 1.5 hours at 40° C. After cooling to room temperature, 25 mg (0.047 mmol) nickel(II)-[bis(diphenylphos-phino)propane]chloride, Ni(dppp)Cl₂, was quickly added. The reaction mixture was stirred for 30 min and then quenched with 3 mL hydrochloric acid (10%). Then the mixture was poured into methanol. T he crude product was filtered off and purified by subsequent Soxhlet extraction with methanol, hexane and acetone to yield P3HT-Br polymer (270 mg, 35%). 1H NMR ¹H (CDCl₃, 600 MHz) . . . 6.96 (m, br), 2.78 (m, br), 1.68 (m, br), 1.34 (m, br), 1.32 (m, br), 1.31 (m, br), 0.89 (m, br); GPC (CHCl₃) Mₙ=8 100; M_{w}=8 700; PDI=1.07.

### Example 2

### Synthesis of a TDPP Homopolymer

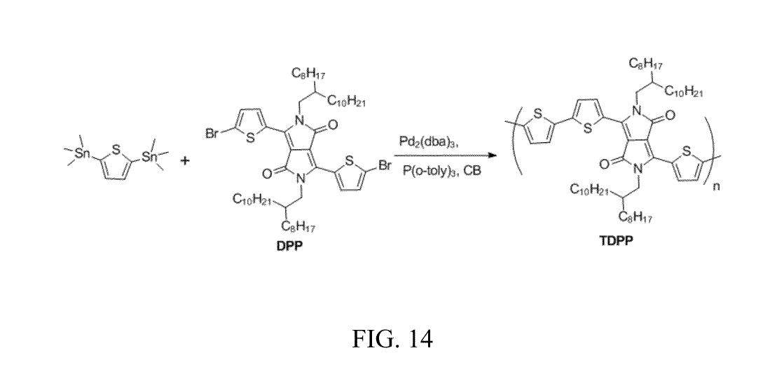

FIG. 14 provides a drawing of a reaction occurring in Example 2. A mixture of bis(stannane)thiophene(102.4 mg, 0.25 mmol), DPP (254.8 mg, 0.25 mmol), Pd₂(dba)₃(4.58 mg, 0.005 mmol) and P(o-toly)₃(6.08 mg, 0.02 mmol) was placed in a 10 mL microwave vial and sealed. Dry chlorobenzene (4 mL) was injected in the vial and the mixture degassed with Ar for 20 mins. The mixture was then heated at 120° C. for 3 min, 150° C. for 3 min and finally at 180° C. for 50 min under microwave conditions. The reaction mixture was allowed to cool to 55° C., 30 mL of o-DCB was added to dissolve any precipitated polymers and the mixture was filtered through a silica plug. After precipitation into methanol (250 mL), the polymer was purified by Soxhlet extraction with methanol and acetone to yield the desired polymer, TDDP (230 mg, 97% yield) as a dark solid. ¹H NMR ¹H (CDCl₃, 600 MHz) . . . 8.92 (m, br), 7.41 (m, br), 7.06 (m, br), 4.02 (m, br),1.93 (m, br), 1.22 (m, br), 0.86 (m, br); GPC (CHCl₃) Mₙ=26 300; M_{w}=60 500; PDI=2.29.

### Example 3

### Synthesis of a P3HT-b-DPP Block Copolymer

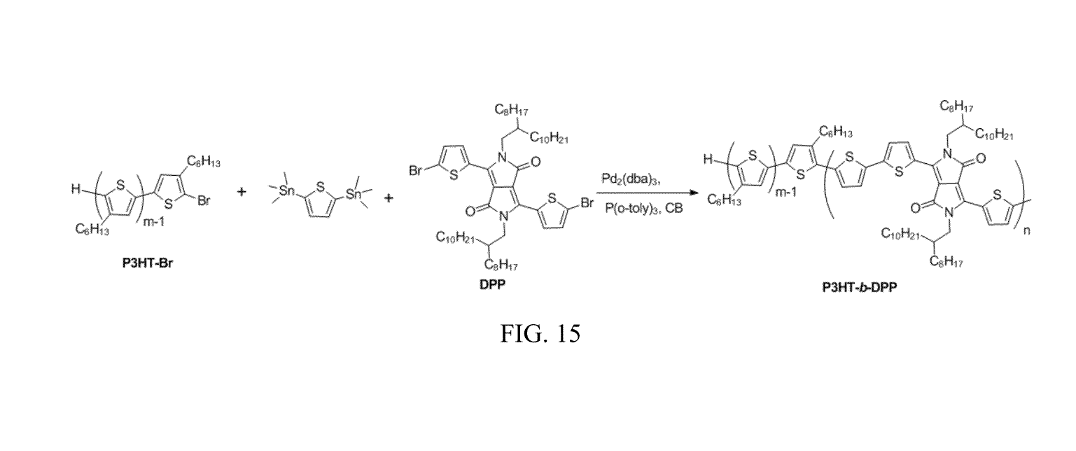

FIG. 15 provides a drawing of a reaction occurring in Example 3. A mixture of P3HT-Br (100 mg, Mₙ=8 k), bis(stannane)thiophene(61.4 mg, 0.15 mmol), DPP (152.8 mg, 0.15 mmol), Pd₂(dba)₃(2.74 mg, 0.003 mmol) and P(o-toly)₃(3.65 mg, 0.012 mmol) was placed in a 10 mL microwave vial and sealed. Dry chlorobenzene (4 ml) was injected in the vial and the mixture degassed with Ar for 20 mins. The mixture was then heated at 120° C. for 3 min, 150° C. for 3 min and finally at 180° C. for 50 min under microwave conditions. The reaction mixture was allowed to cool to 55° C., 30 mL of o-DCB was added to dissolve any precipitated polymers and the mixture was filtered through a silica plug. After precipitation into methanol (250 mL), the polymer was purified by Soxhlet extraction with methanol, hexane and acetone to yield the desired polymer, P3HT₈₇-b-DPP₁₃ (220 mg, 91% yield) as a dark solid. ¹H NMR ¹H (CDCl₃, 600 MHz) . . . 8.92 (m, br), 6.97 (m, br), 4.02 (m, br),2.80 (m, br), 1.95 (m, br), 1.72 (m, br), 1.51 (m, br), 1.43 (m, br), 1.35 (m, br), 0.93 (m, br), 0.85 (m, br); GPC (CHCl₃) Mₙ=37.2 K; M_{w}=69.4 K; PDI=1.86.P3HT₆₃-b-DPP₃₇ can be synthesized to yield the desired polymer (172 mg, 94% yield) by following the same procedure, but change P3HT-Br (42 mg, Mₙ=8 k); GPC (CHCl₃) Mₙ=44 200; M_{w}=84 500; PDI=1.91.

### Example 4

### Synthesis of a PDI End Functionalized DPPF Polymer, PDI-DPPF-PDI

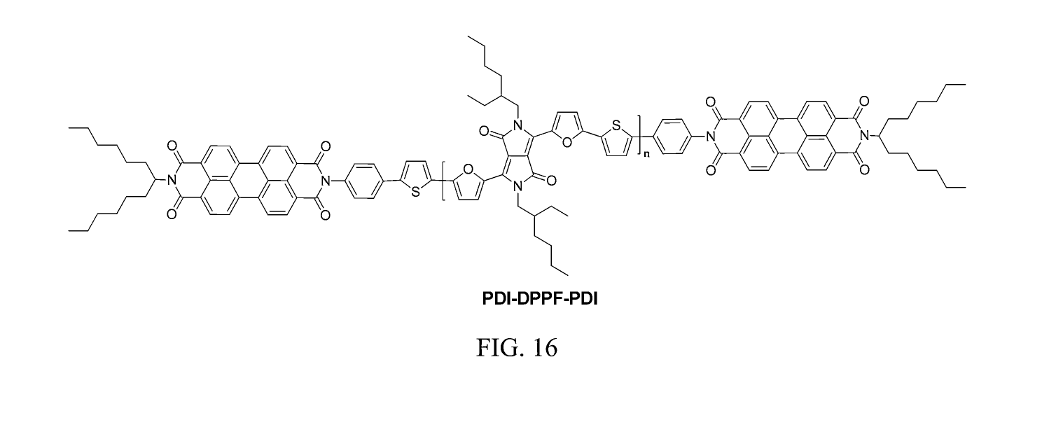

FIG. 16 provides a drawing of a compounds formed by a process disclosed in Example 4. Dibromo-difuryl-DPP (150 mg, 0.231 mmol), 2,5-bis(trimethylstannyl)thiophene (97.4 mg, 0.238 mmol), mono-bromo-perylene diimide (10.4 mg, 0.0143 mmol), Pd₂(dba)₃(4.4 mg, 0.0048 mmol), and P(o-tolyl)₃(5.7 mg, 0.019 mmol) were added to a 10 mL microwave vial equipped with a stir bar. The vial was taken into a glove box and 4.9 mL of chlorobenzene was added and the vial was sealed with a septum. The reaction mixture was heated with stirring in a microwave reactor for 45 min at 180° C. after which the crude mixture was precipitated into 200 mL of methanol, collected by filtration, and washed with methanol, acetone, and hexanes. The crude solid was dissolved in 10 mL of chloroform and passed through a short pad of silica gel, eluting the polymer with chloroform. The polymer solution was concentrated to a volume of -5 mL, precipitated into 200 mL of methanol, collected by filtration using a 0.46 micron nylon filter membrane, and washed with methanol and acetone. 42.6 mg of a dark colored solid were obtained after drying under vacuum. ¹H NMR (CDCl₃, 600 MHz) . . . 8.55 (bs), 7.14 (bs), 6.66 (m), 5.20 (bs), 4.59-3.23 (m), 2.26 (bs), 1.83 (bs), 1.28 (m), 0.88 (bs); GPC (CHCl₃) Mₙ=53.3 kg/mol; M_{w}=114 kg/mol; PDI=2.14.

All numbers recited in the specification and associated claims that refer to values that can be numerically characterized with a value other than a whole number (e.g. a distance) are understood to be modified by the term “about”. Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Furthermore, all publications mentioned herein (see, e.g. Carsten et al., Chem. Rev. 2011, 111, 1493-1528) are incorporated herein by reference to disclose and describe the methods and/or materials in connection with which the publications are cited. Publications cited herein are cited for their disclosure prior to the filing date of the present application. Nothing here is to be construed as an admission that the inventors are not entitled to antedate the publications by virtue of an earlier priority date or prior date of invention. Further the actual publication dates may be different from those shown and require independent verification.

Although the present invention has been described in connection with the working embodiments, it is to be understood that modifications and variations may be utilized without departing from the principles and scope of the invention, as those skilled in the art will readily understand. Accordingly, such modifications may be practiced within the scope of the following claims.

1. A method for making a conjugated polymer having an end group with a selected function, the method comprising forming a reaction mixture comprising:
a monomer compound AA, wherein A comprises a first moiety selected for its ability to form a covalent bond in the polymer chain;
a monomer compound BB, wherein B comprises a second moiety selected for its ability to form a covalent bond in the polymer chain; and
an end capping compound, wherein the end capping compound comprises:
a functional group selected for its ability to modulate an optical or electrical property of the conjugated polymer; and
a reactive group selected for its ability to react with monomer compound AA or monomer compound BB so that the functional group is coupled to an end of the polymer;
wherein the monomer compound AA, the monomer compound BB and the end capping compound are combined so as to:
allow the monomer compound AA and the monomer compound BB to polymerize and form a polymer; and
allow the end capping compound to react with monomer compound AA or monomer compound BB;
so that the conjugated polymer having the end group with the selected function is made.

2. The method of claim 1, wherein the functional group is selected for an ability to modulate:
(a) a charge transport property of the conjugated polymer; or
(b) a light absorption property of the conjugated polymer.

3. The method of claim 2, wherein the end capping compound is selected so that the functional group exhibits an electron or hole mobility >10⁻⁵ cm²/Vs.

4. The method of claim 2, wherein the end capping compound is selected so that the functional group exhibits light absorption coefficients larger than 10⁴ cm⁻¹ in visible/NIR wavelength range in the solid state.

5. The method of claim 1, wherein the end capping compound comprises a polymer or a small molecule.

6. The method of claim 1, wherein AA monomers are selected from a group consisting of di-stannyl-aryl or di-borane-aryl monomers.

7. The method of claim 1, wherein the BB monomers are selected from a group consisting of di-halide, di-triflate or di-tosylate substituted monomers.

8. The process of claim 3, wherein the functional group is selected from a group consisting of a polythiophene containing end group, or a mono-brominated perylene diimide (PDI).

9. The method of claim 1, wherein the method comprises adding a second end capping compound to the reaction mixture, wherein the second end capping compound comprises:
a second functional group selected for its ability to modulate an optical or electrical property of the conjugated polymer; and
a reactive group selected for its ability to react with A or B,
so that the second functional group is coupled to an end of the conjugated polymer.

10. The method of claim 1, wherein the conjugated polymers are all-conjugated block copolymers.

11. The method of claim 1, wherein the monomer compound AA, the monomer compound BB and the end capping compound are selected to form an all-conjugated polymer that self assembles into a phase-separated microstructure comprising donor and acceptor domains.

12. The method of claim 11, wherein the donor and acceptor domain exhibit a characteristic length scale of about 10-20 nanometers.

13. The method of claim 1, further comprising purifying the conjugated polymer having the functionalized end group by a process consisting essentially of: (a) precipitation; and (b) filtration.

14. A conjugated polymer comprising F-(AA-BB)n or F-(AA-BB)n-F, wherein:
F comprises an end capped functional group; and
the polymer is synthesized according to the method of claim 1.

15. A device comprising a conjugated polymer comprising EndCap-(AA-BB)n or EndCap-(AA-BB)n-EndCap, wherein:
the polymer has an end capped functional group that provides charge transporting and/or light absorption properties; and
the polymer is synthesized by the process of claim 1.

16. The device of claim 15, wherein the device comprises a silicon substrate.

17. The device of claim 15, wherein the device is selected from a group consisting of light-emitting diodes, field-effect transistors and photovoltaic cells.

18. A polymerization system comprising:
a monomer compound AA, wherein A comprises a first moiety selected for its ability to form a covalent bond in a polymer chain;
a monomer compound BB, wherein B comprises a second moiety selected for its ability to form a covalent bond in a polymer chain; and
an end capping compound, wherein the end capping compound comprises:
a functional group selected for its ability to modulate an optical or electrical property of a polymer to which the functional group is conjugated; and
a reactive group selected for its ability to react with A or B so that the functional group can be coupled to an end of the polymer;
wherein the monomer compound AA, the monomer compound BB and the end capping compound can be combined in a reaction mixture that forms a copolymer having the functionalized end group conjugated thereon.

19. The polymerization system of claim 18, further comprising:
a solvent in which the monomer compound AA, the monomer compound BB and the end capping compound can be combined in the reaction mixture; or
a reaction vessel in which the monomer compound AA, the monomer compound BB and the end capping compound can be combined.

20. The polymerization system of claim 18, wherein the monomer compound AA, the monomer compound BB and the end capping compound are disposed together within a kit comprising a plurality of containers.
